(19) United States
(12) Patent Application Publication
(10) Pub. No.: US 2026/0255960 A1
(43) Pub. Date: Aug. 27, 2026

(54) INTEGRATED CIRCUIT PACKAGE INCLUDING THINNED DIE USING A MICRO-ABRASION APPROACH

(71) Applicant: Intel Corporation, Santa Clara, CA (US)

(72) Inventors: Sangeon Lee, Chandler, AZ (US); Xiao Lu, Chandler, AZ (US); Tingting Gao, Chandler, AZ (US); Jalal Nasser, Chandler, AZ (US); Tarek Gebrael, Chandler, AZ (US)

(73) Assignee: Intel Corporation, Santa Clara, CA (US)

(21) Appl. No.: 19/062,285

(22) Filed: Feb. 25, 2025

(51) Int. Cl. H01L 23/373; H01L 23/00; H01L 25/07

(52) U.S. Cl. CPC H10W 40/255; H10W 72/07354; H10W 72/347; H10W 72/877; H10W 74/15; H10W 90/00; H10W 90/724; H10W 90/734

(57) ABSTRACT

Disclosed herein are microelectronic assemblies, as well as related apparatuses and methods. In some embodiments, a microelectronic assembly may include a substrate having a surface; a die having a first surface and an opposing second surface, wherein the first surface of the die is coupled to the surface of the substrate by interconnects, and wherein the second surface of the die has a roughness between 100 nanometers and 500 nanometers; a cooling apparatus thermally coupled to the second surface of the die; and a material between the second surface of the die and the cooling apparatus. In some embodiments, the material includes a thermal interface material. In some embodiments, the material includes a solder-based thermal interface material in direct contact with the second surface of the die and with the cooling apparatus.

### BACKGROUND

Integrated circuit (IC) devices (e.g., dies) are typically coupled together in a multi-die IC package to integrate features or functionality and to facilitate connections to other components, such as package substrates.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is a side, cross-sectional view of an exemplary microelectronic assembly, in accordance with various embodiments.

FIG. 1B is a magnified view of a die of the microelectronic assembly of FIG. 1A, in accordance with various embodiments.

FIG. 2 is a side, cross-sectional view of another exemplary microelectronic assembly, in accordance with various embodiments.

FIG. 3 is a side, cross-sectional view of another exemplary microelectronic assembly, in accordance with various embodiments.

FIG. 4 is a side, cross-sectional view of another exemplary microelectronic assembly, in accordance with various embodiments.

FIG. 5 is a side, cross-sectional view of another exemplary microelectronic assembly, in accordance with various embodiments.

FIGS. 6A and 6B are side, cross-sectional views of an exemplary thinning process in manufacturing a microelectronic assembly, in accordance with various embodiments.

FIGS. 7A-7C are side, cross-sectional views of an exemplary process for providing a thermal interface material and a cooling apparatus in manufacturing a microelectronic assembly, in accordance with various embodiments.

FIG. 8 is a flow diagram of an example method of manufacturing a microelectronic assembly, in accordance with various embodiments.

FIG. 9 is a cross-sectional view of a device package that includes one or more microelectronic assemblies in accordance with any of the embodiments disclosed herein.

FIG. 10 is a cross-sectional side view of a device assembly that includes one or more microelectronic assemblies in accordance with any of the embodiments disclosed herein.

FIG. 11 is a block diagram of an example computing device that includes one or more microelectronic assemblies in accordance with any of the embodiments disclosed herein.

### DETAILED DESCRIPTION

Packaging semiconductor devices presents several challenges. One such challenge is encountered with the demand for miniaturization of semiconductor devices, continually requiring thinner form factors and multiple thermal processing operations. The resulting IC packages may suffer from warpage generated as a result of the mismatch in the coefficient of thermal expansion (CTE) between a thin die and a substrate. Fabrication of an IC package is a multi-stage process, which includes patterning, deposition, etching, and metallization. In final processing, a resulting IC die can be separated and packaged. A first plurality of solder bump structures (e.g., solder bumps, balls, pads, pillar bumps (e.g., copper pillar bumps), etc.) of a generally uniform size can be positioned between the die and a substrate, and the die and substrate can be heated to similar temperatures. The die can then be lowered onto the substrate, in order to mechanically and electrically couple the die to the substrate. Heat can be applied via a solder reflow process to re-melt the solder bumps and attach the die to the substrate. Attachment of the die to the substrate (i.e., primary substrate), to form the IC package, is referred to as a “first level interconnects” (FLI). The FLI may further be surrounded by an underfill material to strengthen the mechanical connection between the die and the substrate. One or more such IC packages can be physically and electrically coupled to a secondary substrate, such as a printed circuit board (PCB) or a motherboard. Attachment of the IC package(s) directly to the secondary substrate, such as by soldering, is referred to as a “second level interconnects” (SLI).

Manufacturing of an IC package can involve multiple thermal cycling (or processing) operations. For instance, a substrate may be heated to add solder balls (e.g., flip-chip or controlled collapse chip connection (C4) solder balls) to a substrate. The substrate may again be heated one or more times for die placement and solder reflow. Another thermal cycle may be added if epoxy, for example, is used in the assembly process as an underfill material. An underfilling process, such as capillary-flow underfilling, relies upon capillary pressure of the underfill material, to flow between the substrate and the die. Yet another thermal cycle may be used to incorporate the IC package into an electronic assembly. The multiple thermal cycles can lead to warpage of components of a resulting IC package or electronic assembly. Warpage refers to a bending or twist or general lack of flatness in an overall IC package, for example, including particularly the plane formed by solder joint locations. Such warpage is caused by a difference in CTE between one part or component and another. The problem of IC package warpage can be exacerbated in larger packages due to the larger size, and can also be exacerbated when soldering temperatures become higher. Recently, the use of lead-free solders has become more prevalent on certain product types. This lead-free solder generally requires a higher soldering temperature than prior solders.

Warpage can pose a problem in IC packages, in particular, when thinning attached die. A lack of flatness can occur where the entire package warps so that it is curved or bent or otherwise non-flat. Standard die thinning technique involves a combination of mechanical grinding and polishing or etching. Employing the traditional mechanical grinding method (e.g., linear-based surface contact thinning process) without compensating for warpage typically results in die with non-uniform thicknesses.

Another challenge in IC packages occurs when a thermal interface material (TIM) and a cooling apparatus are used as a thermal solution. A TIM may be between a top surface of a die (e.g., the thinned surface of the die) and a cooling apparatus. The traditional methods of thinning dies may not compensate for warpage and generally result in non-uniform die thicknesses and, consequently, non-uniform TIM thicknesses, which significantly degrades thermal performance. Die surface coplanarity contributes significantly to thermal performance. Dies with substantially planar surfaces (e.g., dies having substantially uniform and equal thicknesses) facilitate effective thermal management by enabling a TIM to have a substantially uniform thickness. Conversely, uneven die thicknesses may lead to reduced thermal performance as well as other various issues, such as, reduced strength, poor electrical properties, high thermal resistance, and operational failures. An IC package having a TIM with uneven thicknesses between the dies and the cooling apparatus may reduce thermal performance by disrupting heat dissipation. Additionally, stress becomes concentrated at thinner TIM portions, potentially causing delamination and premature failure during IC package operation.

A TIM may include, for example, a polymer-based thermal interface material (PTIM) or a solder-based thermal interface material (STIM). Generally, the thermal conductivity of a PTIM is inferior to that of a STIM, and a PTIM typically exhibits lower heat dissipation capabilities compared to an STIM. This limitation may hinder the performance of devices or products that utilize a PTIM. However, although an STIM has a high thermal conductivity (e.g., greater than 82 Watts per meter-Kelvin) and a low modulus, a STIM usually requires a backside metallization (BSM) layer on a surface of a die. A BSM layer enables the STIM to form strong bonds with the die through intermetallic bonding. The BSM process includes depositing metal layers onto the surface of the die to establish conductive pathways or links between the die and the STIM. Typically, a BSM layer includes depositing gold (Au) using a sputter process, which is costly and requires vacuum (e.g., a manufacturing process having more operations and more complexity). Another challenge in using a TIM includes the tendency for the TIM to “bleed” and spread out onto other components, which may reduce thermal dissipation and IC package performance.

Some traditional methods of thinning dies may compensate for warpage, for example, by flattening the assembly and, subsequently, grinding. Different methods used different strategies for flattening the assembly. One example includes dispensing a mold material over the dies, applying heat and pressure to harden the mold material, grinding the top surface once the assembly is flattened, and removing the mold material. Another example includes applying heat to the assembly and grinding the top surface once the assembly is flattened. A third example includes attaching a heat spreader to a top surface of the assembly, applying heat to the assembly to flatten, removing the heat spreader, and grinding a top surface of the assembly. These traditional thinning methods add operations and complexity to the manufacturing process. Further, these operations may not completely flatten the assembly, so they are likely to create inconsistencies in die thickness and, as a result, an uneven TIM thickness. Additionally, conventional grinding methods may induce mechanical stress and heat during the process, leading to stress, cracks, and scratches on the die.

Structures and methods that enable using a TIM that has a substantially uniform thickness may be desired. Further, structures and methods that enable using an STIM without a BSM layer also may be desired. Various ones of the embodiments disclosed herein may help achieve improved performance of IC packages, relative to conventional approaches, by using a simplified thinning process that accounts for assembly warpage without adding manufacturing operations or complexity. Disclosed herein is a thinning process that operates without direct contact with the die, thereby avoiding the issue of die cracking commonly associated with conventional mechanical grinding methods. Instead, dies are thinned using erosion induced by a particle stream. Consistently maintaining an even abrasive density per unit area guarantees uniform erosion across the surface, ensuring consistent material removal per unit area. This uniform erosion approach preserves thickness uniformity even on curved (e.g., warped) die surfaces. This process addresses multiple challenges simultaneously. First, it effectively thins dies in a curvilinear manner while maintaining consistent warpage, eliminating the need for a flattening process. Second, the erosion-based thinning approach increases a roughness of the surface of the die leading to improved TIM adhesion and prevention of leakage issues during thermal cycling so that enhanced thermal dissipation and durability may be observed. Finally, the process establishes robust bonds between the TIM and the die through increased surface roughness and eliminates the need for a BSM layer, which ultimately results in reduced costs and less complexity.

Accordingly, microelectronic assemblies, related devices and methods, are disclosed herein. Microelectronic assemblies, related devices and methods, are disclosed herein. In some embodiments, a microelectronic assembly may include a substrate having a surface; a die having a first surface and an opposing second surface, wherein the first surface of the die is coupled to the surface of the substrate by interconnects, and wherein the second surface of the die has a roughness between 100 nanometers and 500 nanometers; a cooling apparatus thermally coupled to the second surface of the die; and a thermal interface material (TIM) between the second surface of the die and the cooling apparatus.

Each of the structures, assemblies, packages, methods, devices, and systems of the present disclosure may have several innovative aspects, no single one of which is solely responsible for all the desirable attributes disclosed herein. Details of one or more implementations of the subject matter described in this specification are stated in the description below and the accompanying drawings.

In the following detailed description, various aspects of the illustrative implementations may be described using terms commonly employed by those skilled in the art to convey the substance of their work to others skilled in the art.

The terms “circuit” and “circuitry” mean one or more passive and/or active electrical and/or electronic components that are arranged to cooperate with one another to provide a desired function. The terms also refer to analog circuitry, digital circuitry, hard wired circuitry, programmable circuitry, microcontroller circuitry and/or any other type of physical hardware electrical and/or electronic component.

The term “integrated circuit” means a circuit that is integrated into a monolithic semiconductor or analogous material.

In some embodiments, the IC dies disclosed herein may include substantially monocrystalline semiconductors, such as silicon or germanium, as a base material on which integrated circuits are fabricated with traditional semiconductor processing methods. The semiconductor base material may include, for example, N-type or P-type materials. Dies may include, for example, a crystalline base material formed using a bulk silicon (or other bulk semiconductor material) or a semiconductor-on-insulator (SOI, e.g., a silicon-on-insulator) structure. In some other embodiments, the base material of one or more of the IC dies may include alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-N, group III-V, group II-VI, or group IV materials. In yet other embodiments, the base material may include compound semiconductors, for example, with a first sub-lattice of at least one element from group III of the periodic table (e.g., Al, Ga, In), and a second sub-lattice of at least one element of group V of the periodic table (e.g., P, As, Sb). In yet other embodiments, the base material may include an intrinsic IV or III-V semiconductor material or alloy, not intentionally doped with any electrically active impurity; in alternate embodiments, nominal impurity dopant levels may be present. In still other embodiments, dies may include a non-crystalline material, such as polymers; for example, the base material may include silica-filled epoxy. In other embodiments, the base material may include high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the base material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N-or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc. Although a few examples of the material for dies are described here, any material or structure that may serve as a foundation (e.g., base material) upon which IC circuits and structures as described herein may be built falls within the spirit and scope of the present disclosure.

Unless described otherwise, IC dies described herein include one or more IC structures (or, simply, “ICs”) implementing (i.e., configured to perform) certain functionality. In one such example, the term “memory die” may be used to describe a die that includes one or more ICs implementing memory circuitry (e.g., ICs implementing one or more of memory devices, memory arrays, control logic configured to control the memory devices and arrays, etc.). In another such example, the term “compute die” may be used to describe a die that includes one or more ICs implementing logic/compute circuitry (e.g., ICs implementing one or more of input/output (I/O) functions, arithmetic operations, pipelining of data, etc.).

In another example, the terms “package” and “IC package” are synonymous, as are the terms “die” and “IC die.” Note that the terms “chip,” “chiplet,” “die,” and “IC die” are used interchangeably herein.

The term “optical structure” includes arrangements of forms fabricated in ICs to receive, transform and/or transmit optical signals as described herein. It may include optical conductors such as waveguides, electromagnetic radiation sources such as lasers and light-emitting diodes (LEDs) and electro-optical devices such as photodetectors.

In various embodiments, any photonic IC (PIC) described herein may include a semiconductor material, for example, N-type or P-type materials. The PIC may include, for example, a crystalline base material formed using a bulk silicon (or other bulk semiconductor material) or a SOI structure (or, in general, a semiconductor-on-insulator structure). In some embodiments, the PIC may be formed using alternative materials, which may or may not be combined with silicon, that include, but are not limited to, lithium niobite, indium phosphide, silicon dioxide, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-N or group IV materials. In some embodiments, the PIC may include a non-crystalline material, such as polymers. In some embodiments, the PIC may be formed on a printed circuit board. In some embodiments, the PIC may be inhomogeneous, including a carrier material (such as glass or silicon carbide) as a base material with a thin semiconductor layer over which is an active side comprising transistors and like components. Although a few examples of the material for the PIC are described here, any material or structure that may serve as a foundation upon which the PIC may be built falls within the spirit and scope of the present disclosure.

The term “insulating” means “electrically insulating,” the term “conducting” means “electrically conducting,” unless otherwise specified. With reference to optical signals and/or devices, components and elements that operate on or using optical signals, the term “conducting” can also mean “optically conducting.”

The terms “oxide,” “carbide,” “nitride,” etc. refer to compounds containing, respectively, oxygen, carbon, nitrogen, etc.

The term “high-k dielectric” refers to a material having a higher dielectric constant than silicon oxide, while the term “low-k dielectric” refers to a material having a lower dielectric constant than silicon oxide.

The term “insulating material” refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon and alumina or a combination thereof. They may include dielectric materials, high polarizability materials, and/or piezoelectric materials. They may be transparent or opaque without departing from the scope of the present disclosure. Further examples of insulating materials are underfills and molds or mold-like materials used in packaging applications, including for example, materials used in organic interposers, package supports and other such components.

In various embodiments, elements associated with an IC may include, for example, transistors, diodes, power sources, resistors, capacitors, inductors, sensors, transceivers, receivers, antennas, etc. In various embodiments, elements associated with an IC may include those that are monolithically integrated within an IC, mounted on an IC, or those connected to an IC. The ICs described herein may be either analog or digital and may be used in a number of applications, such as microprocessors, optoelectronics, logic blocks, audio amplifiers, etc., depending on the components associated with the IC. The ICs described herein may be employed in a single IC die or as part of a chipset for executing one or more related functions in a computer.

In various embodiments of the present disclosure, transistors described herein may be field-effect transistors (FETs), e.g., metal oxide semiconductor (MOS) FETs (MOSFETs). In general, a FET is a three-terminal device that includes source, drain, and gate terminals and uses electric field to control current flowing through the device. A FET typically includes a channel material, a source region and a drain regions provided in and/or over the channel material, and a gate stack that includes a gate electrode material, alternatively referred to as a “work function” material, provided over a portion of the channel material (the “channel portion”) between the source and the drain regions, and optionally, also includes a gate dielectric material between the gate electrode material and the channel material.

In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are included in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “lines,” “wires,” “metal lines” or “trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a PIC, “interconnect” may also describe any element formed of a material that is optically conductive for providing optical connectivity to one or more elements associated with the PIC. In such cases, the term “interconnect” may refer to optical waveguides (e.g., structures that guide and confine light waves), including optical fiber, optical splitters, optical combiners, optical couplers, and optical vias.

The term “waveguide” refers to any structure that acts to guide the propagation of light from one location to another location typically through a substrate material such as silicon or glass. In various examples, waveguides can be formed from silicon, doped silicon, silicon nitride, glasses such as silica (e.g., silicon dioxide or SiO2), borosilicate (e.g., 70-80 wt % SiO2, 7-13 wt % of B2O3, 4-8 wt % Na2O or K2O, and 2-8 wt % of Al2O3) and so forth. Waveguides may be formed using various techniques including but not limited to forming waveguides in situ. For example, in some embodiments, waveguides may be formed in situ in glass using low temperature glass-to-glass bonding or by laser direct writing. Waveguides formed in situ may have lower loss characteristics.

The term “conductive trace” may be used to describe an electrically conductive element isolated by an insulating material. Within IC dies, such insulating material includes interlayer low-k dielectric that is provided within the IC die. Within package substrates, and printed circuit boards (PCBs) such insulating material includes organic materials such as Ajinomoto Buildup Film (ABF), polyimides, or epoxy resin. Such conductive lines are typically arranged in several levels, or several layers, of metallization stacks.

The term “conductive via” may be used to describe an electrically conductive element that interconnects two or more conductive lines of different levels of a metallization stack. To that end, a via may be provided substantially perpendicularly to the plane of an IC die/chip or a support structure over which an IC structure is provided and may interconnect two conductive lines in adjacent levels or two conductive lines in non-adjacent levels.

The term “package substrate” may be used to describe any substrate material that facilitates the packaging together of any collection of semiconductor dies and/or other electrical components such as passive electrical components. As used herein, a package substrate may be formed of any material including, but not limited to, insulating materials such as resin impregnated glass fibers (e.g., PCB or Printed Wiring Boards (PWB)), glass, ceramic, silicon, silicon carbide, etc. In addition, as used herein, a package substrate may refer to a substrate that includes buildup layers (e.g., ABF layers).

The term “metallization stack” may be used to refer to a stack of one or more interconnects for providing connectivity to different circuit components of an IC die/chip and/or a package substrate.

As used herein, the term “pitch” of interconnects refers to a center-to-center distance between adjacent interconnects.

In context of a stack of dies coupled to one another or in context of a die coupled to a package substate, the term “interconnect” may also refer to, respectively, die-to-die (DTD) interconnects and die-to-package substrate (DTPS) interconnects. DTD interconnects may also be referred to as first-level interconnects (FLI). DTPS interconnects may also be referred to as Second-Level Interconnects (SLI). Although not specifically shown in all of the present illustrations in order to not clutter the drawings, when DTD or DTPS interconnects are described, a surface of a first die may include a first set of conductive contacts, and a surface of a second die or a package substrate may include a second set of conductive contacts. One or more conductive contacts of the first set may then be electrically and mechanically coupled to some of the conductive contacts of the second set by the DTD or DTPS interconnects. In some embodiments, the pitch of the DTD interconnects may be different from the pitch of the DTPS interconnects, although, in other embodiments, these pitches may be substantially the same.

It will be recognized that one more levels of underfill (e.g., organic polymer material such as benzotriazole, imidazole, polyimide, or epoxy) may be provided in an IC package described herein and may not be labeled in order to avoid cluttering the drawings. In various embodiments, the levels of underfill may include the same or different insulating materials. In some embodiments, the levels of underfill may include thermoset epoxies with silicon oxide particles; in some embodiments, the levels of underfill may include any suitable material that can perform underfill functions such as supporting the dies and reducing thermal stress on interconnects. In some embodiments, the choice of underfill material may be based on design considerations, such as form factor, size, stress, operating conditions, etc. ; in other embodiments, the choice of underfill material may be based on material properties and processing conditions, such as cure temperature, glass transition temperature, viscosity and chemical resistance, among other factors; in some embodiments, the choice of underfill material may be based on both design and processing considerations.

In some embodiments, one or more levels of solder resist (e.g., epoxy liquid, liquid photoimageable dielectrics, dry film photoimageable dielectrics, acrylics, solvents) may be provided in an IC package described herein and may not be labeled or shown to avoid cluttering the drawings. Solder resist may be a liquid or dry film material including photoimageable dielectrics. In some embodiments, solder resist may be non-photoimageable.

The terms “substantially,” “close,” “approximately,” “near,” and “about,” generally refer to being within +/31 20% of a target value unless otherwise specified more narrowly for a particular value (e.g., within +/−5% or 10% of a target value) based on the context of a particular value as described herein or as known in the art.

Terms indicating orientation of various elements, e.g., “coplanar,” “perpendicular,” “orthogonal,” “parallel,” or any other angle between the elements, generally refer to being within +/−5%-20% of a target value based on the context of a particular value as described herein or as known in the art.

The term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices.

The description uses the phrases “in an embodiment” or “in embodiments,” which may each refer to one or more of the same or different embodiments.

Furthermore, the terms “comprising,” “including,” “having,” and the like, as used with respect to embodiments of the present disclosure, are synonymous.

The disclosure may use perspective-based descriptions such as “above,” “below,” “top,” “bottom,” and “side”; such descriptions are used to facilitate the discussion and are not intended to restrict the application of disclosed embodiments.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

The term “dispose” as used herein refers to position, location, placement, and/or arrangement rather than to any particular method of formation.

The term “between,” when used with reference to measurement ranges, is inclusive of the ends of the measurement ranges.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used herein, the notation “A/B/C” means (A), (B), and/or (C).

Although certain elements may be referred to in the singular herein, such elements may include multiple sub-elements. For example, “an electrically conductive material” may include one or more electrically conductive materials. In another example, “a dielectric material” may include one or more dielectric materials.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale.

Coordinates, when included in the accompanying drawings, identify a thickness or a height by z-dimension, a width by y-dimension, and a length by x-dimension. A diameter or cross section may be identified by xy-dimension.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated.

Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images, average grain size of a material may be determined. Also, in such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

Note that in the figures, various components (e.g., interconnects) are shown as aligned (e.g., at respective interfaces) merely for ease of illustration; in actuality, some or all of them may be misaligned. In addition, there may be other components, such as bond-pads, landing pads, metallization, etc. present in the assembly that are not shown in the figures to prevent cluttering. Further, the figures are intended to show relative arrangements of the components within their assemblies, and, in general, such assemblies may include other components that are not illustrated (e.g., various interfacial layers or various other components related to optical functionality, electrical connectivity, or thermal mitigation). For example, in some further embodiments, the assembly as shown in the figures may include more dies along with other electrical components. Additionally, although some components of the assemblies are illustrated in the figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

In the drawings, a particular number and arrangement of structures and components are presented for illustrative purposes and any desired number or arrangement of such structures and components may be present in various embodiments.

Further, unless otherwise specified, the structures shown in the figures may take any suitable form or shape according to material properties, fabrication processes, and operating conditions.

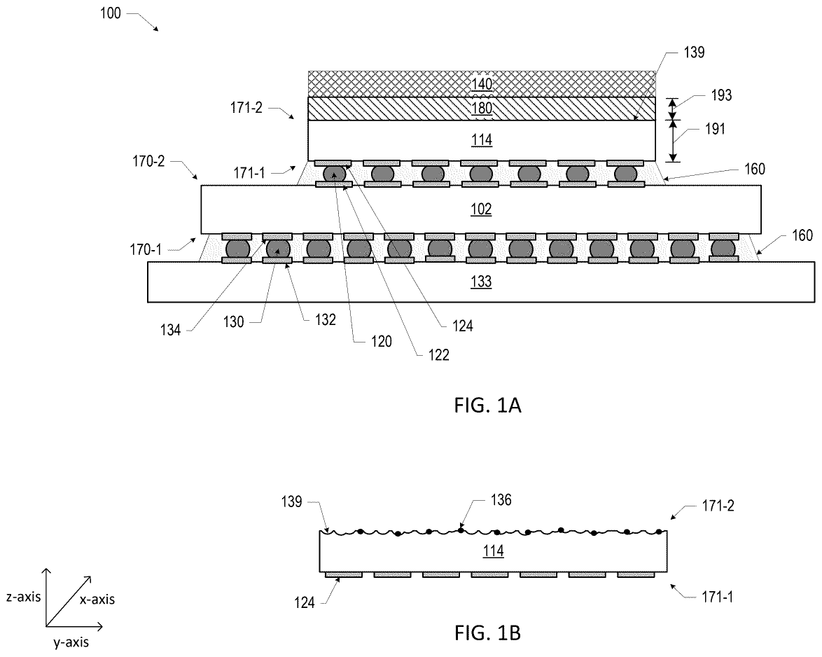

For convenience, if a collection of drawings designated with different letters are present (e.g., FIGS. 1A and 1B), such a collection may be referred to herein without the letters (e.g., as “FIG. 1”). Similarly, if a collection of reference numerals designated with different numbers and/or letters are present (e.g., 114-1, 114-2), such a collection may be referred to herein without the numbers (e.g., as “114”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

FIG. 1A is a side, cross-sectional view of a microelectronic assembly 100, in accordance with various embodiments. The microelectronic assembly 100 may include a die 114 having a first surface 171-1 and an opposing second surface 171-2 with a roughness 139 between 100 nanometers and 500 nanometers, a TIM 180 on the second surface 171-2 of the die 114, and a cooling apparatus 140 on the TIM 180 and in thermal contact with the die 114. The roughness 139 of the second surface 171-2 of the die 114 may improve physical contact with the TIM 180 and further improve thermal conduction from the die 114 through the cooling apparatus 140. The roughness 139 of the second surface 171-2 of the die 114 also may improve physical attachment of the TIM 180 to the die 114. By providing a more stable attachment for the TIM 180, the TIM is less likely to seep and a BSM layer between the second surface 171-2 of the die 114 and the TIM 180 may be omitted such that the TIM 180 is in direct physical contact with the second surface 171-2 of the die 144 and with the cooling apparatus 140.

The TIM 180 may be made of any suitable material and may include, for example, a PTIM, a STIM, a liquid-metal-based thermal interface material (YTIM), a vertical graphical carbon-based thermal interface material (VCTIM), a thermal paste, or a thermal grease. A STIM may include a solder material, such as tin (Sn), silver (AG), copper (Cu), gold (Au), lead (Pb), indium (In), or antimony (Sb), among others. The TIM 180 may have any suitable thickness 193. For example, in some embodiments, the TIM 180 may have a thickness 193 between about 0.05 millimeters and 2 millimeters. In some embodiments, the TIM 180 may include a STIM and may have a thickness between about 0.05 millimeters and 1 millimeter. A thickness 193 of the TIM 180 may be substantially uniform (e.g., a thickness 193 does not vary by more than +/−10 %).

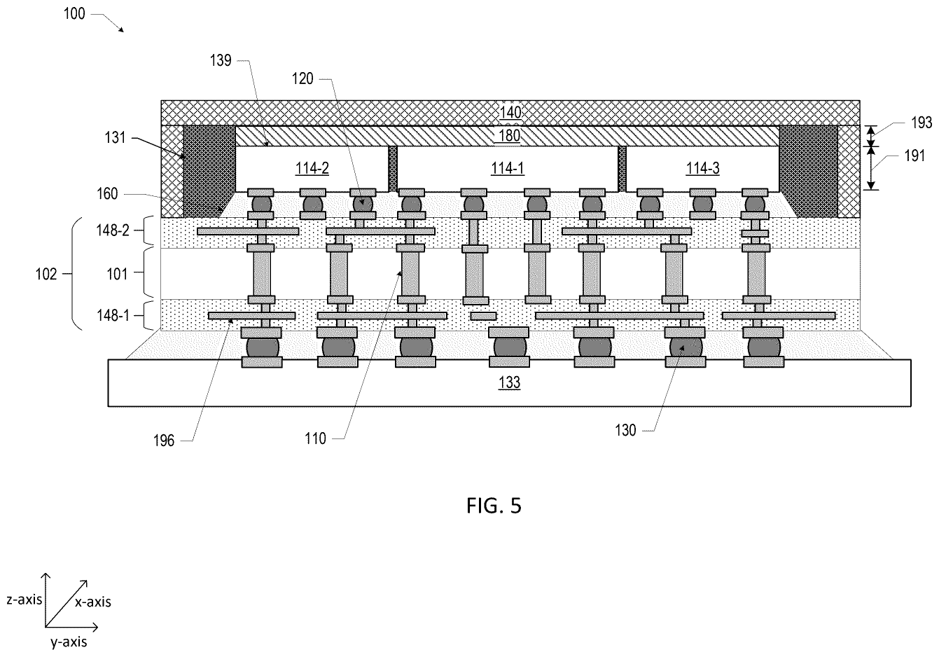

The cooling apparatus 140 may include any suitable cooling apparatus, for example, a heat spreader, an integrated heat spreader, a heat sink, or a cold plate, among others. In some embodiments, the cooling apparatus 140 may include a conductive base having vertical fins (not shown) or other features. The cooling apparatus may be coupled to, and in thermal contact with, the second surface 171-2 of the die 114 via the TIM 180 to dissipate heat from the die 114. In some embodiments, the cooling apparatus 140 may include portions (e.g., sides or legs, as shown in FIG. 5) that extend down and attach to the second surface 170-2 of the package substrate 102. The cooling apparatus 140 may further include a fluid inlet and fluid outlet, and pipes or connections to a heat exchanger, a chiller, or other device for cooling the fluid before returning the fluid to the fluid inlet (not shown). The fluid may be any suitable liquid or gas, such as a coolant, for example, water, fluorochemical liquids, silicone oil, ethylene glycol water, poly-alpha-olefin, or silicate ester, or helium, argon, or nitrogen, that may be circulated, usually by a pump or a fan (not shown), to dissipate heat more efficiently from the second surface 171-2 of the die 114. The fluid may also include additives to prevent corrosion of the different components or to allow operation at higher/lower temperatures (e.g. additives to water to decrease its freezing point or increase its boiling point). The coolant used may depend on the coolant's properties, including viscosity and heat capacity, circulation flow rate, and the temperature rise during device operation. The cooling apparatus 140 may have any suitable dimensions and any suitable shape. The cooling apparatus may be made from any suitable conductive material, such as a metal. In some embodiments, the cooling apparatus 140 may include copper, gold, nickel, silver, aluminum, or other metals or metal alloys, for example.

A die 114 may have any suitable thickness 191. For example, in some embodiments, a die 114 may have a thickness 191 between 275 microns and 750 microns. A thickness 191 of a die 114 may be substantially uniform (e.g., a thickness 191 does not vary by more than +/−10 %). The die 114 disclosed herein may include an insulating material (e.g., a dielectric material formed in multiple layers, as known in the art) and multiple conductive pathways formed through the insulating material. In some embodiments, the insulating material of a die 114 may include a dielectric material, such as silicon dioxide, silicon nitride, oxynitride, polyimide materials, glass reinforced epoxy matrix materials, or a low-k or ultra low-k dielectric (e.g., carbon-doped dielectrics, fluorine-doped dielectrics, porous dielectrics, organic polymeric dielectrics, photo-imageable dielectrics, and/or benzocyclobutene-based polymers). In some embodiments, the insulating material of a die 114 may include a semiconductor material, such as silicon, germanium, or a III-V material (e.g., gallium nitride), and one or more additional materials. For example, an insulating material may include silicon oxide or silicon nitride. The conductive pathways in a die 114 may include conductive traces and/or conductive vias, and may connect any of the conductive contacts in the die 114 in any suitable manner (e.g., connecting multiple conductive contacts on a same surface or on different surfaces of the die 114). The die 114 may include any suitable circuitry. For example, in some embodiments, the die 114 may be an active or passive die, and the die 114 may include input/output circuitry, a processor, high bandwidth memory, or enhanced dynamic random access memory (EDRAM).

The microelectronic assembly may further include a package substrate 102 having a first surface 170-1 and an opposing second surface 170-2. The first surface 171-1 of the die 114 may be coupled to the second surface 170-2 of the package substrate 102 by interconnects 120. In particular, the package substrate 102 may include first conductive contacts 134 on a first surface 170-1 and second conductive contacts 122 on an opposing second surface 170-2, the die 114 may include conductive contacts 124 on a first surface 171-1 and an opposing second surface 171-2, and the conductive contacts 124 on the first surface of the die 114 may be coupled to the second conductive contacts 122 on the second surface 170-2 of the package substrate 102 via first level interconnects 120. In some embodiments, interconnects 120 may include solder, as shown. In some embodiments, an underfill material 160, such as a mold compound or an epoxy, may be disposed around the first level interconnects 120. In some embodiments, the underfill material 160 may extend around the die 114 (e.g., along sidewalls of the die 114, as shown in FIG. 3).

The package substrate 102 may include an insulating material and one or more conductive pathways through the insulating material, in accordance with various embodiments. In some embodiments, the insulating material may be provided by a single material, while in other embodiments, the insulating material may include different layers formed of different materials. For example, a “base” layer of insulating material may be provided by a glass fiber reinforced core, a rigid carrier, or a peelable core panel, for example, while additional layers of insulating material may be provided by an epoxy-based laminate. In some embodiments, the package substrate 102 may be an organic substrate. The conductive pathways (not shown) in the package substrate 102 may couple the die 114 to the circuit board 133 (e.g., via the first level interconnects 120 and the second-level interconnects 130).

The microelectronic assembly of FIG. 1A also may include a circuit board 133 having conductive contacts 132 on a surface. The first conductive contacts 134 on the first surface 170-1 of the package substrate 102 may be coupled to the conductive contacts 132 on the circuit board 133 by second-level interconnects 130. In some embodiments, an underfill material 160 may be between the package substrate 102 and the circuit board 133 around the second-level interconnects 130. The second-level interconnects 130 illustrated in FIG. 1A are solder balls (e.g., for a BGA arrangement), but any suitable second-level interconnects 130 may be used (e.g., pins in a pin grid array arrangement or lands in a land grid array arrangement). The circuit board 133 may be a motherboard, for example, and may have other components attached to it (not shown). The circuit board 133 may include conductive pathways and other conductive contacts (not shown) for routing power, ground, and signals through the circuit board 133, as known in the art. In some embodiments, the second-level interconnects 130 may not couple the package substrate 102 to a circuit board 133, but may instead couple the package substrate 102 to another IC package, an interposer, or any other suitable component.

A number of elements are not illustrated in FIG. 1A, but may be present in microelectronic assembly 100, for example, additional active components, such as dies, or additional passive components, such as surface-mount resistors, capacitors, and/or inductors, may be disposed on the top surface or the bottom surface of the package substrate 102, and may be thermally connected to the cooling apparatus 140 via a TIM 180. Although FIG. 1A depicts a single, surface mounted die 114, the microelectronic assemblies 100 disclosed herein may have any suitable number of dies 114, for example, additional surface mounted dies in thermal contact with the cooling apparatus 140 via a TIM 180. More generally, the microelectronic assemblies 100 disclosed herein may have any suitable arrangement of the dies 114, and any number of the dies 114.

Many of the elements of the microelectronic assembly 100 of FIG. 1A are included in other ones of the accompanying figures; the discussion of these elements is not repeated when discussing these figures, and any of these elements may take any of the forms disclosed herein. Some of the elements of the microelectronic assembly 100 of FIG. 1A are not included in other ones of the accompanying figures for simplicity, but a microelectronic assembly 100 may include these omitted elements.

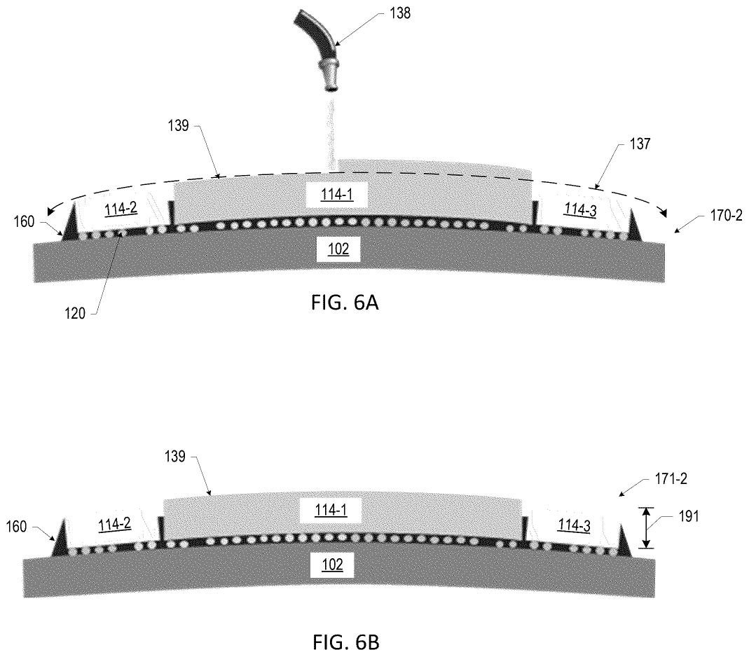

FIG. 1B is a magnified view of a die of the microelectronic assembly of FIG. 1A, in accordance with various embodiments. A die 114 may include a first surface 171-1 having conductive contacts 124 and an opposing second surface 171-2 having a roughness 139. The roughness 139 may be formed by thinning the die 114 using a micro-abrasive particle stream (e.g., the micro-abrasive particle stream 138, as shown in FIG. 6A). A micro-abrasive particle stream hovers above the second surface 171-2 of the die 114 and relies on erosion induced by a micro-particle stream to remove a material of the die 114. By consistently maintaining an even abrasive density per unit area, the micro-abrasive particle stream ensures uniform erosion across the surface, resulting in consistent material removal per unit area and eliminating the need for a flattening process. This uniform erosion enables thickness uniformity even on a curved (e.g., warped) die surface (e.g., the second surface 171-2). The micro-abrasive particle stream functions by blasting countless grains of micro-particles onto the second surface 171-2 of the die 114, which removes material (e.g., thins the die 114), imparts texture (e.g., surface roughness 139), and embeds micro-particles 136 on the second surface 171-2 of the die 114 (e.g., the thinned surface). The micro-abrasive particle stream may include any suitable micro-particles 136, for example, a metal oxide, such as cerium dioxide, silica, magnetite, zirconia, ceria, titania, graphene oxide, alumina, talc nanoparticles, glass beads, silicon carbide, or sodium bicarbonate, among others.

A material composition of the micro-particles 136, a micro-particle size (e.g., based on porosity, dent density, and/or dent size), and/or a roughness 139 may be determined using any suitable technique, including, for example, Energy Dispersive X-Ray Spectroscopy (EDX) mapping, scanning electron microscope (SEM) inspection, X-ray Photoelectron Spectroscopy (XPS), and X-ray diffraction spectroscopy (XRD), FTIR (Fourier transform infrared spectroscopy).

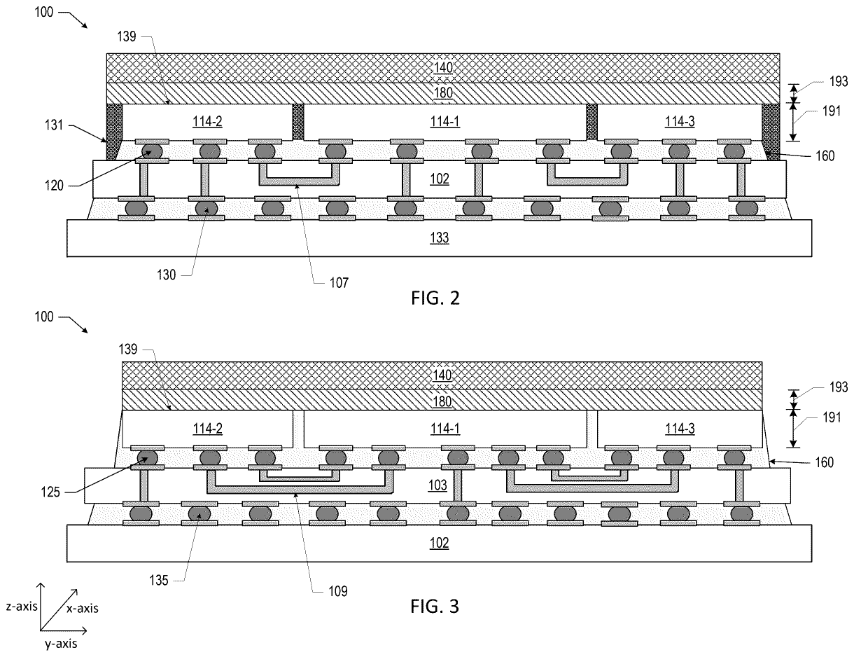

FIG. 2 is a side, cross-sectional view of another example microelectronic assembly, in accordance with various embodiments. The embodiment shown in the figure is similar to that of FIG. 1A, except that the microelectronic assembly 100 includes a plurality of die 114 (e.g., die 114-1, 114-2, 114-3) and an insulating material 131 surrounding the plurality of die 114. In some embodiments, the insulating material 131 may include an organic material, such as a mold material, a polyimide, or a polybenzoxazole. In some embodiments, the insulating material 131 may include a mold material, a resin material, an epoxy material, or other inorganic material. FIG. 2 further illustrates conductive pathways 107 in the package substrate 102. The conductive pathways 107 in the package substrate 102 may electrically couple one or more of the die 114-1, 114-2, 114-3 to each other or to the circuit board 133.

FIG. 3 is a side, cross-sectional view of another example microelectronic assembly, in accordance with various embodiments. The embodiment shown in the figure is similar to that of FIG. 2, except that the microelectronic assembly 100 includes an interposer 103 having conductive pathways 109 and the underfill material 160 extends around and between the die 114-1, 114-2, 114-3. In particular, an interposer 103 may be coupled to the die 114-1, 114-2, 114-3 by interconnects 125 and coupled to the package substrate 102 by interconnects 135. Interconnects 125, 135 may include any suitable interconnects, for example, as described above for interconnects 120, 130. In some embodiments, interconnects 125, 135 may include solder, as shown. In some embodiments, a material of the interposer 103 includes an inorganic material such as silicon. In some embodiments, a material of the interposer 103 includes an organic material such as an epoxy resin. The conductive pathways 109 in the interposer 103 may electrically couple one or more of the die 114-1, 114-2, 114-3 to each other or to the package substrate 102. In some embodiments, the die 114-1 includes a system-on-chip and the die 114-2, 114-3 include high bandwidth memory. In some embodiments, the package substrate 102 is electrically coupled to a circuit board 133 (not shown), similar to FIG. 1A. In some embodiments, the interposer 103 is electrically coupled to a circuit board 133 instead of a package substrate 102.

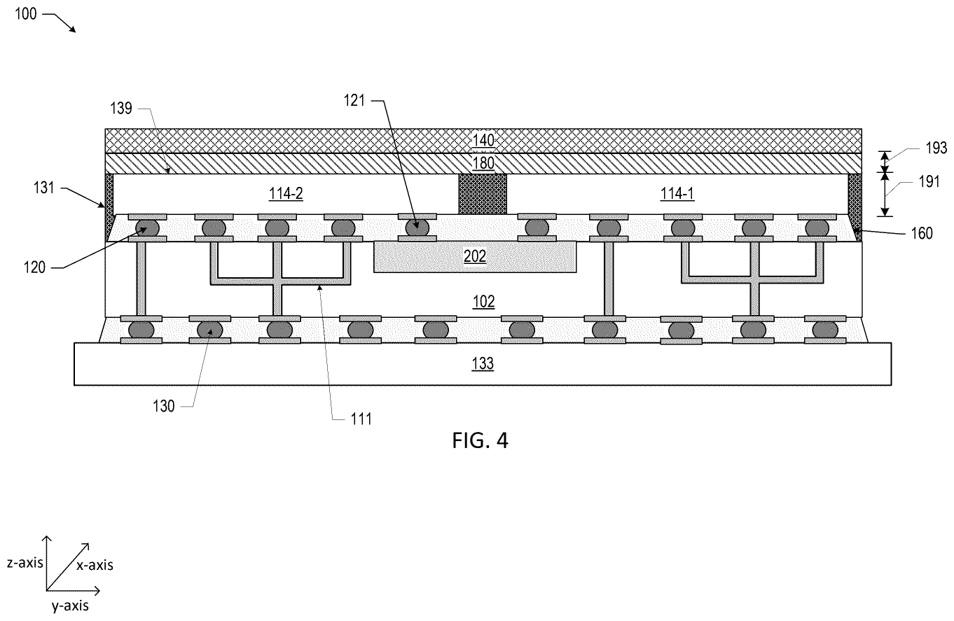

FIG. 4 is a side, cross-sectional view of another example microelectronic assembly, in accordance with various embodiments. The embodiment shown in the figure is similar to that of FIG. 2, except that the microelectronic assembly 100 includes die 114-1, 114-2, and a package substrate 102 having conductive pathways 111 and a bridge die 202 at least partially within the package substrate 102. A bridge die 202 may be coupled to die 114-1 and die 114-2 by interconnects 121. Interconnects 121 may include any suitable interconnects, for example, as described above for interconnects 120, 130. In some embodiments, interconnects 121 may include solder, as shown. A bridge die 202 may include appropriate circuitry on/in a semiconductor substrate to connect at silicon-interconnect speeds with a small footprint. In some embodiments, bridge die 202 may include active components, such as transistors and diodes in addition to bridge circuitry including metallization traces, vias and passive components for enabling electrical coupling between two ICs; in other embodiments, bridge die 202 may include bridge circuitry including metallization traces, vias and passive components for enabling electrical coupling between die 114-1 and die 114-2, and may not include active components.

FIG. 5 is a side, cross-sectional view of another example microelectronic assembly, in accordance with various embodiments. The embodiment shown in the figure is similar to that of FIG. 2, except that the package substrate 102 includes a first redistribution layer (RDL) 148-1 at a bottom surface of a glass core 101 and a second RDL 148-2 at a top surface of the glass core 101. The first and second RDLs 148 1, 148-2 may include conductive pathways 196 (e.g., including conductive traces and/or conductive vias, as shown) through a dielectric material. The first and second RDLs 148-1, 148-2 may be manufactured using any suitable technique, such as a semi-additive process, a subtractive etching technique, or other conventional substrate package techniques. In some embodiments, a dielectric material of the RDL 148 may include bismaleimide triazine (BT) resin, polyimide materials, epoxy materials (e.g., glass reinforced epoxy matrix materials, epoxy build-up films, or the like), mold materials, oxide-based materials (e.g., silicon dioxide or spin on oxide), or low-k and ultra low-k dielectric (e.g., carbon-doped dielectrics, fluorine-doped dielectrics, porous dielectrics, and organic polymeric dielectrics). The glass core 101 may include through glass vias (TGVs) 110 that electrically couple the first and second RDLs 148-1, 148-2. As used herein, the glass core 101 with the second RDL 148-2 and/or the first RDL 148-1 may be referred to as a package substrate 102. TGVs 110 in glass core 101 may enable power, ground and signal connectivity to components located on either side of the glass core 101, for example, between dies 114-1, 114-2, 114-3 and a circuit board 133. FIG. 5 further illustrates a cooling apparatus 140 having sides or legs that extend down and attach to the top surface of the second RDL 148-2. Although FIG. 5 shows an insulating material 131 in the space between the die 114 and the cooling apparatus 140, in some embodiments, an underfill material (e.g., underfill material 160) or air may be in the space between the die 114 and the cooling apparatus 140.

Any suitable techniques may be used to manufacture the microelectronic assemblies 100 disclosed herein. For example, FIGS. 6A and 6B are side, cross-sectional views of an exemplary process for manufacturing a microelectronic assembly, in accordance with various embodiments. Although the operations discussed with reference to FIGS. 6A and 6B illustrate a particular assembly, these operations may be performed on any suitable assembly. Further, additional operations which are not illustrated may also be performed without departing from the scope of the present disclosure. Also, various ones of the operations discussed herein with respect to FIGS. 6A and 6B may be modified in accordance with the present disclosure to fabricate others of microelectronic assembly 100 disclosed herein.

FIG. 6A illustrates an assembly subsequent to coupling die 114 (e.g., die 114-1, 114-2, 114-3) by forming first level interconnects 120 on a second surface 170-2 of a package substrate 102, depositing an underfill material 160 on and around die 114 and around interconnects 120, and thinning the die 114 using a micro-abrasive particle stream 138. In some embodiments, the first level interconnects 120 may include solder. In such embodiments, the assembly of FIG. 6A may be subjected to a solder reflow process during which solder components of the first level interconnects 120 melt and bond to mechanically and electrically couple the die 114 to the top surface 170-2 of the package substrate 102 causing the assembly to warp 137, as shown by the dotted line. If a material (e.g., an insulating material 131, as shown in FIG. 2 or an underfill material 160, as shown in FIG. 3) surround the die 114, the material also may be removed by the micro-abrasive particle stream 138.

FIG. 6B illustrates an assembly subsequent to thinning the die 114 (e.g., using the micro-abrasive particle stream 138 that accounts for the warpage 137 as shown in FIG. 6A) such that the die 114 have a thickness 191 that is substantially uniform and the die 114-1, 114-2, 114-3 have a thickness 191 that is substantially equal. The die 114-1, 114-2, 114-3 further include a second surface 171-2 having a roughness 139.

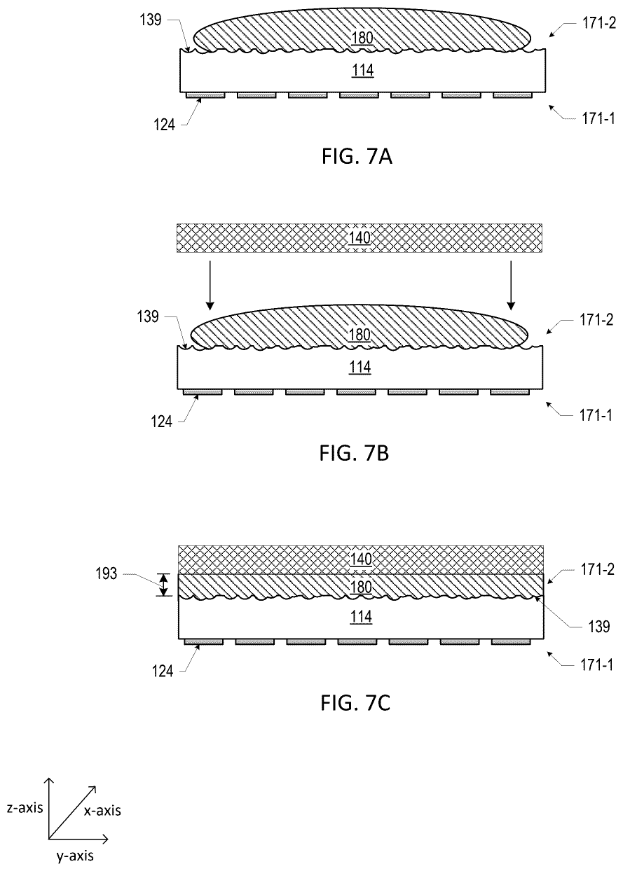

FIGS. 7A-7C are side, cross-sectional views of an exemplary process for manufacturing a microelectronic assembly, in accordance with various embodiments. FIG. 7A illustrates an assembly including a die 114 having a first surface 171-1 with conductive contacts 124 and a second surface 171-2 with a roughness 139 subsequent to dispensing a TIM 180 on a second surface 171-2 of the die 114. FIG. 7B illustrates an assembly subsequent to aligning a cooling apparatus 140 with a top surface of the assembly of FIG. 7A. FIG. 7C illustrates an assembly subsequent to attaching a cooling apparatus 140 to a second surface 171-2 of the die 114 with a TIM 180 between the cooling apparatus 140 and the second surface 171-2 of the die 114, where a thickness 193 of the TIM 180 is substantially uniform and the TIM 180 does not seep and instead physically couples to the roughness 139 of the second surface 171-2 of the die 114. Although FIGS. 7A-7C illustrates a single die 114, the operations described with reference to FIGS. 7A-7C may be applied to an assembly including multiple die 114 electrically coupled to a package substrate 102 or other component (e.g., as shown in FIG. 6B).

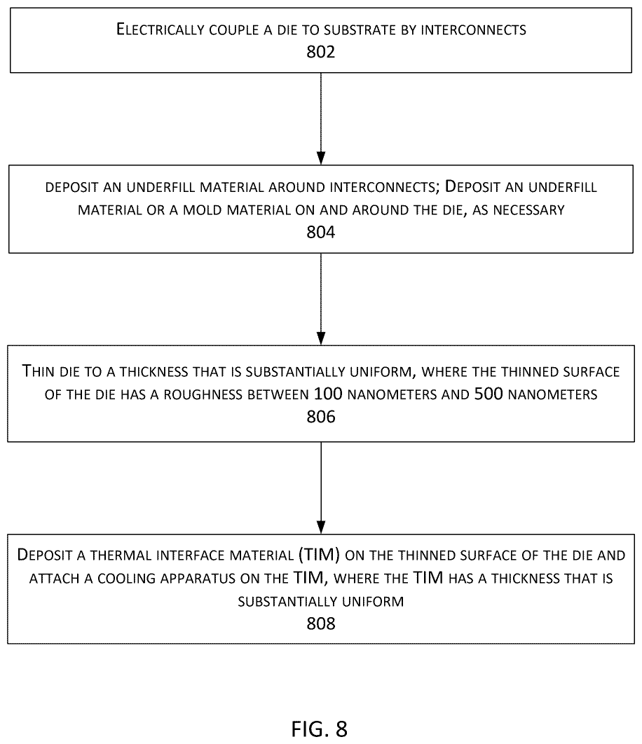

FIG. 8 is a flow diagram of an example method of manufacturing a microelectronic assembly, in accordance with various embodiments. At 802, a die 114 may be coupled to a substrate 102 by forming first level interconnects 120. At 804, an underfill material 160 may be dispensed around the first level interconnects 120 and, optionally, a material, such as an insulating material 131 in FIG. 2 or an underfill material 160 in FIG. 3 may be deposited around and between the die 114. At 806, a second surface 171-2 of the die 114 may be thinned to a thickness that is substantially uniform and substantially equal, and the second surface 171-2 of the die 114 may have a roughness 139 between 100 nanometers and 500 nanometers. The die 114 may be thinned using a micro-abrasive particle stream 138 as shown in FIG. 6. At 808, a TIM 180 may be deposited on the thinned second surface 171-2 of the die 114 and a cooling apparatus 140 may be attached to the TIM 180 such that the TIM 180 has a thickness that is substantially uniform.

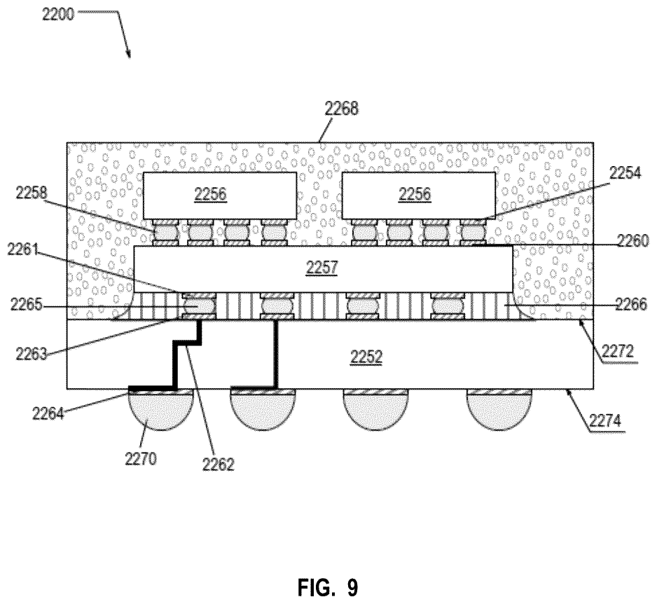

The packages disclosed herein, e.g., any of the embodiments shown in FIGS. 1-7 or any further embodiments described herein, may be included in any suitable electronic component. FIGS. 9-11 illustrate various examples of packages, assemblies, and devices that may be used with or include any of the IC packages as disclosed herein.

FIG. 9 is a side, cross-sectional view of an example IC package 2200 that may include IC packages in accordance with any of the embodiments disclosed herein. In some embodiments, the IC package 2200 may be a SiP.

As shown in the figure, package substrate 2252 may be formed of an insulator (e.g., a ceramic, a buildup film, an epoxy film having filler particles therein, etc.), and may have conductive pathways extending through the insulator between first face 2272 and second face 2274, or between different locations on first face 2272, and/or between different locations on second face 2274. These conductive pathways may take the form of any of the interconnect structures including lines and/or vias.

Package substrate 2252 may include conductive contacts 2263 that are coupled to conductive pathway 2262 through package substrate 2252, allowing circuitry within dies 2256 and/or interposer 2257 to electrically couple to various ones of conductive contacts 2264 (or to other devices included in package substrate 2252, not shown).

IC package 2200 may include interposer 2257 coupled to package substrate 2252 via conductive contacts 2261 of interposer 2257, first-level interconnects 2265, and conductive contacts 2263 of package substrate 2252. First-level interconnects 2265 illustrated in the figure are solder bumps, but any suitable first-level interconnects 2265 may be used, such as solder bumps, solder posts, or bond wires.

IC package 2200 may include one or more dies 2256 coupled to interposer 2257 via conductive contacts 2254 of dies 2256, first-level interconnects 2258, and conductive contacts 2260 of interposer 2257. Conductive contacts 2260 may be coupled to conductive pathways (not shown) through interposer 2257, allowing circuitry within dies 2256 to electrically couple to various ones of conductive contacts 2261 (or to other devices included in interposer 2257, not shown). First-level interconnects 2258 illustrated in the figure are solder bumps, but any suitable first-level interconnects 2258 may be used, such as solder bumps, solder posts, or bond wires. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

In some embodiments, underfill material 2266 may be disposed between package substrate 2252 and interposer 2257 around first-level interconnects 2265, and mold 2268 may be disposed around dies 2256 and interposer 2257 and in contact with package substrate 2252. In some embodiments, underfill material 2266 may be the same as mold 2268. Example materials that may be used for underfill material 2266 and mold 2268 are epoxies as suitable. Second-level interconnects 2270 may be coupled to conductive contacts 2264. Second-level interconnects 2270 illustrated in the figure are solder balls (e.g., for a ball grid array (BGA) arrangement), but any suitable second-level interconnects 2270 may be used (e.g., pins in a pin grid array arrangement or lands in a land grid array arrangement). Second-level interconnects 2270 may be used to couple IC package 2200 to another component, such as a circuit board (e.g., a motherboard), an interposer, or another IC package, as known in the art and as discussed below with reference to FIG. 7.

In embodiments in which IC package 2200 includes multiple dies 2256, IC package 2200 may be referred to as a multi-chip package (MCP). Dies 2256 may include circuitry to perform any desired functionality. For example, besides one or more of dies 2256 being microelectronic assembly 100 as described herein, one or more of dies 2256 may be logic dies (e.g., silicon-based dies), one or more of dies 2256 may be memory dies (e.g., HBM), etc. In some embodiments, any of dies 2256 may be implemented as discussed with reference to any of the previous figures. In some embodiments, at least some of dies 2256 may not include implementations as described herein.

Although IC package 2200 illustrated in the figure is a flip-chip package, other package architectures may be used. For example, IC package 2200 may be a BGA package, such as an embedded wafer-level ball grid array (eWLB) package. In another example, IC package 2200 may be a wafer-level chip scale package (WLCSP) or a panel fan-out (FO) package. Although two dies 2256 are illustrated in IC package 2200, IC package 2200 may include any desired number of dies 2256. IC package 2200 may include additional passive components, such as surface-mount resistors, capacitors, and inductors disposed over first face 2272 or second face 2274 of package substrate 2252, or on either face of interposer 2257. More generally, IC package 2200 may include any other active or passive components known in the art.

In some embodiments, no interposer 2257 may be included in IC package 2200; instead, dies 2256 may be coupled directly to conductive contacts 2263 at first face 2272 by first-level interconnects 2265.

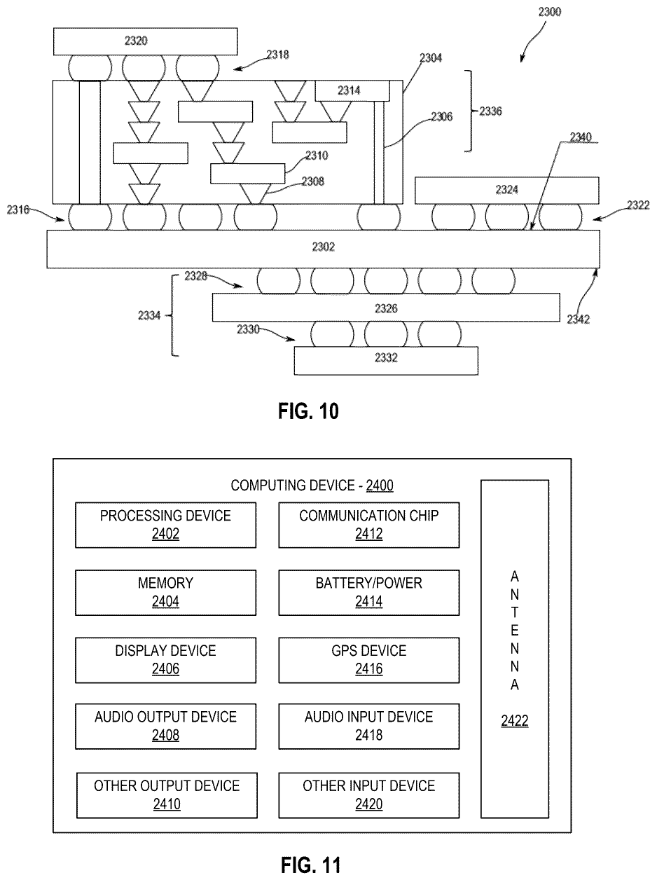

FIG. 10 is a cross-sectional side view of an IC device assembly 2300 that may include components having one or more microelectronic assembly 100 in accordance with any of the embodiments disclosed herein. IC device assembly 2300 includes a number of components disposed over a circuit board 2302 (which may be, e.g., a motherboard). IC device assembly 2300 includes components disposed over a first face 2340 of circuit board 2302 and an opposing second face 2342 of circuit board 2302; generally, components may be disposed over one or both faces 2340 and 2342. In particular, any suitable ones of the components of IC device assembly 2300 may include any of the one or more microelectronic assembly 100 in accordance with any of the embodiments disclosed herein; e.g., any of the IC packages discussed below with reference to IC device assembly 2300 may take the form of any of the embodiments of IC package 2200 discussed above with reference to FIG. 9.

In some embodiments, circuit board 2302 may be a PCB including multiple metal layers separated from one another by layers of insulator and interconnected by electrically conductive vias. Any one or more of the metal layers may be formed in a desired circuit pattern to route electrical signals (optionally in conjunction with other metal layers) between the components coupled to circuit board 2302. In other embodiments, circuit board 2302 may be a non-PCB package substrate.

As illustrated in the figure, in some embodiments, IC device assembly 2300 may include a package-on-interposer structure 2336 coupled to first face 2340 of circuit board 2302 by coupling components 2316. Coupling components 2316 may electrically and mechanically couple package-on-interposer structure 2336 to circuit board 2302, and may include solder balls (as shown), male and female portions of a socket, an adhesive, an underfill material, and/or any other suitable electrical and/or mechanical coupling structure.

Package-on-interposer structure 2336 may include IC package 2320 coupled to interposer 2304 by coupling components 2318. Coupling components 2318 may take any suitable form depending on desired functionalities, such as the forms discussed above with reference to coupling components 2316. In some embodiments, IC package 2320 may be or include IC package 2200, e.g., as described above with reference to FIG. 9.

Although a single IC package 2320 is shown in the figure, multiple IC packages may be coupled to interposer 2304; indeed, additional interposers may be coupled to interposer 2304. Interposer 2304 may provide an intervening package substrate used to bridge circuit board 2302 and IC package 2320. Generally, interposer 2304 may redistribute a connection to a wider pitch or reroute a connection to a different connection. For example, interposer 2304 may couple IC package 2320 to a BGA of coupling components 2316 for coupling to circuit board 2302.

In the embodiment illustrated in the figure, IC package 2320 and circuit board 2302 are attached to opposing sides of interposer 2304. In other embodiments, IC package 2320 and circuit board 2302 may be attached to a same side of interposer 2304. In some embodiments, three or more components may be interconnected by way of interposer 2304.

Interposer 2304 may be formed of an epoxy resin, a fiberglass-reinforced epoxy resin, a ceramic material, or a polymer material such as polyimide. In some implementations, interposer 2304 may be formed of alternate rigid or flexible materials that may include the same materials described above for use in a semiconductor substrate, such as silicon, germanium, and other group III-V and group IV materials. Interposer 2304 may include metal interconnects 2310 and vias 2308, including but not limited to TSVs 2306. Interposer 2304 may further include embedded devices 2314, including both passive and active devices. Such devices may include, but are not limited to, capacitors, decoupling capacitors, resistors, inductors, fuses, diodes, transformers, sensors, ESD devices, and memory devices. More complex devices such as radio frequency (RF) devices, power amplifiers, power management devices, antennas, arrays, sensors, and microelectromechanical systems (MEMS) devices may also be formed on interposer 2304. Package-on-interposer structure 2336 may take the form of any of the package-on-interposer structures known in the art.

In some embodiments, IC device assembly 2300 may include an IC package 2324 coupled to first face 2340 of circuit board 2302 by coupling components 2322. Coupling components 2322 may take the form of any of the embodiments discussed above with reference to coupling components 2316, and IC package 2324 may take the form of any of the embodiments discussed above with reference to IC package 2320.

In some embodiments, IC device assembly 2300 may include a package-on-package structure 2334 coupled to second face 2342 of circuit board 2302 by coupling components 2328. Package-on-package structure 2334 may include an IC package 2326 and an IC package 2332 coupled together by coupling components 2330 such that IC package 2326 is disposed between circuit board 2302 and IC package 2332. Coupling components 2328 and 2330 may take the form of any of the embodiments of coupling components 2316 discussed above, and IC packages 2326 and/or 2332 may take the form of any of the embodiments of IC package 2320 discussed above. Package-on-package structure 2334 may be configured in accordance with any of the package-on-package structures known in the art.

FIG. 11 is a block diagram of an example computing device 2400 that may include one or more components having one or more IC packages in accordance with any of the embodiments disclosed herein. For example, any suitable ones of the components of computing device 2400 may include a microelectronic assembly 100 in accordance with any of the embodiments disclosed herein. In another example, any one or more of the components of computing device 2400 may include any embodiments of IC package 2200 (e.g., as shown in FIG. 9). In yet another example, any one or more of the components of computing device 2400 may include an IC device assembly 2300 (e.g., as shown in FIG. 7).

A number of components are illustrated in the figure as included in computing device 2400, but any one or more of these components may be omitted or duplicated, as suitable for the application. In some embodiments, some or all of the components included in computing device 2400 may be attached to one or more motherboards. In some embodiments, some or all of these components are fabricated onto a single system-on-chip (SOC) die.

Additionally, in various embodiments, computing device 2400 may not include one or more of the components illustrated in the figure, but computing device 2400 may include interface circuitry for coupling to the one or more components. For example, computing device 2400 may not include a display device 2406, but may include display device interface circuitry (e.g., a connector and driver circuitry) to which display device 2406 may be coupled. In another set of examples, computing device 2400 may not include an audio input device 2418 or an audio output device 2408, but may include audio input or output device interface circuitry (e.g., connectors and supporting circuitry) to which audio input device 2418 or audio output device 2408 may be coupled.

Computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. Processing device 2402 may include one or more DSPs, ASICs, CPUs, GPUs, cryptoprocessors (specialized processors that execute cryptographic algorithms within hardware), server processors, or any other suitable processing devices. Computing device 2400 may include a memory 2404, which may itself include one or more memory devices such as volatile memory (e.g., dynamic random access memory (DRAM)), nonvolatile memory (e.g., read-only memory (ROM)), flash memory, solid-state memory, and/or a hard drive. In some embodiments, memory 2404 may include memory that shares a die with processing device 2402. This memory may be used as cache memory and may include embedded dynamic random access memory (eDRAM) or spin transfer torque magnetic random access memory (STT-MRAM).

In some embodiments, computing device 2400 may include a communication chip 2412 (e.g., one or more communication chips). For example, communication chip 2412 may be configured for managing wireless communications for the transfer of data to and from computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), LTE project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 2412 may operate in accordance with other wireless protocols in other embodiments. Computing device 2400 may include an antenna 2422 to facilitate wireless communications and/or to receive other wireless communications (such as AM or FM radio transmissions).

In some embodiments, communication chip 2412 may manage wired communications, such as electrical, optical, or any other suitable communication protocols (e.g., the Ethernet). As noted above, communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

Computing device 2400 may include battery/power circuitry 2414. Battery/power circuitry 2414 may include one or more energy storage devices (e.g., batteries or capacitors) and/or circuitry for coupling components of computing device 2400 to an energy source separate from computing device 2400 (e.g., AC line power).

Computing device 2400 may include a display device 2406 (or corresponding interface circuitry, as discussed above). Display device 2406 may include any visual indicators, such as a heads-up display, a computer monitor, a projector, a touchscreen display, a liquid crystal display (LCD), a light-emitting diode display, or a flat panel display, for example.

Computing device 2400 may include audio output device 2408 (or corresponding interface circuitry, as discussed above). Audio output device 2408 may include any device that generates an audible indicator, such as speakers, headsets, or earbuds, for example.

Computing device 2400 may include audio input device 2418 (or corresponding interface circuitry, as discussed above). Audio input device 2418 may include any device that generates a signal representative of a sound, such as microphones, microphone arrays, or digital instruments (e.g., instruments having a musical instrument digital interface (MIDI) output).

Computing device 2400 may include a GPS device 2416 (or corresponding interface circuitry, as discussed above). GPS device 2416 may be in communication with a satellite-based system and may receive a location of computing device 2400, as known in the art.

Computing device 2400 may include other output device 2410 (or corresponding interface circuitry, as discussed above). Examples of other output device 2410 may include an audio codec, a video codec, a printer, a wired or wireless transmitter for providing information to other devices, or an additional storage device.

Computing device 2400 may include other input device 2420 (or corresponding interface circuitry, as discussed above). Examples of other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, computing device 2400 may be any other electronic device that processes data.

The descriptions of illustrated implementations of the disclosure, including what is described in the abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

The following paragraphs provide various examples of the embodiments disclosed herein.

Example 1 provides a microelectronic assembly, including a substrate having a surface; a die having a first surface and an opposing second surface, where the first surface of the die is coupled to the surface of the substrate by interconnects, and where the second surface of the die has a roughness between 100 nanometers and 500 nanometers; a cooling apparatus thermally coupled to the second surface of the die; and a material between the second surface of the die and the cooling apparatus.

Example 2 provides the microelectronic assembly of example 1, where a thickness of the material is between 0.05 millimeters and 2 millimeters, and the thickness is substantially uniform.

Example 3 provides the microelectronic assembly of example 1 or 2, where the material includes a thermal interface material (TIM).

Example 4 provides the microelectronic assembly of example 3, where the TIM includes a solder-based thermal interface material (STIM) and the STIM is in direct contact with the second surface of the die and with the cooling apparatus.

Example 5 provides the microelectronic assembly of any one of examples 1-4, where the cooling apparatus includes a heat sink, a heat spreader, an integrated heat spreader, or a cold plate.

Example 6 provides the microelectronic assembly of any one of examples 1-5, where the interconnects include solder, and the microelectronic assembly further including an underfill material between the first surface of the die and the surface of the substrate around the interconnects.

Example 7 provides the microelectronic assembly of any one of examples 1-6, where the die is a first die, and the microelectronic assembly further including a second die within the substrate and coupled to the first die.

Example 8 provides the microelectronic assembly of any one of examples 1-7, where the substrate includes a glass core.

Example 9 provides the microelectronic assembly of any one of examples 1-8, where the surface of the substrate is a second surface and the substrate further having a first surface opposite the second surface, and the microelectronic assembly further including a circuit board, where the circuit board is coupled to the first surface of the substrate.

Example 10 provides an integrated circuit (IC) package, including a substrate having a surface and including conductive pathways through a dielectric material; a die having a first surface and an opposing second surface, where the first surface of the die is coupled to the second surface of the substrate by interconnects, and where the die has a first thickness that is substantially uniform; a cooling apparatus thermally coupled to the second surface of the die; and a solder-based thermal interface material (STIM) between the second surface of the die and the cooling apparatus, where the STIM is in direct contact with the second surface of the die and with the cooling apparatus.

Example 11 provides the IC package of example 10, where the second surface of the die has a roughness between 100 nanometers and 500 nanometers.

Example 12 provides the IC package of example 10 or 11, where the cooling apparatus includes a heat sink, a heat spreader, an integrated heat spreader, or a cold plate.

Example 13 provides the IC package of any one of examples 10-12, where the interconnects include solder, and the IC package further including an underfill material between the first surface of the die and the surface of the substrate around the interconnects.

Example 14 provides the IC package of any one of examples 10-13, where the die is one of a plurality of dies.

Example 15 provides the IC package of any one of examples 10-14, where a thickness of the STIM between the second surface of the die and the cooling apparatus is between 0.05 millimeters and 1 millimeter.

Example 16 provides the IC package of any one of examples 10-15, where the substrate includes a glass core.

Example 17 provides the IC package of any one of examples 10-16, where the surface of the substrate is a second surface and the substrate further having a first surface opposite the second surface, and the IC package further including a circuit board coupled to the first surface of the substrate.

Example 18 provides a computing device, including a substrate having a surface and including conductive pathways through a dielectric material; a first die having a first surface and an opposing second surface, where the first surface of the first die is coupled to the second surface of the substrate by first interconnects, and where the second surface of the first die has a roughness between 100 nanometers and 500 nanometers; a second die having a first surface and an opposing second surface, where the first surface of the second die is coupled to the second surface of the substrate by second interconnects, where the second surface of the second die has a roughness between 100 nanometers and 500 nanometers; a cooling apparatus thermally coupled to the second surface of the first die and the second surface of the second die; and a material between the second surface of the first die and the cooling apparatus and between the second surface of the second die and the cooling apparatus.

Example 19 provides the computing device of example 18, where the first die has a first thickness that is substantially uniform, where the second die has a second thickness that is substantially uniform, and where the first thickness is substantially equal to the second thickness.

Example 20 provides the computing device of example 18 or 19, where the material includes a solder-based thermal interface material (STIM).

Example 21 provides the computing device of example 20, where the STIM is in direct contact with the second surface of the first die, the second surface of the second die, and the cooling apparatus.

Example 22 provides the computing device of any one of examples 18-21, where the cooling apparatus includes a heat sink, a heat spreader, an integrated heat spreader, or a cold plate.

Example 23 provides the computing device of any one of examples 18-22, where the first interconnects and the second interconnects include solder, and the computing device further including an underfill material between the first surface of the first die and the first surface of the second die and the surface of the substrate around the first interconnects and the second interconnects.

Example 24 provides the computing device of any one of examples 18-23, further including a third die within the substrate and coupled to the first die and the second die.

Example 25 provides the computing device of any one of examples 18-24, where the substrate includes a glass core.

Example 26 provides the computing device of any one of examples 18-25, where the surface of the substrate is a second surface and the substrate further having a first surface opposite the second surface, and the computing device further including a circuit board coupled to the first surface of the substrate.

Example 27 provides the computing device of any one of examples 18-26, where a thickness of the material is between 0.05 millimeters and 2 millimeters, and the thickness is substantially uniform.

1. A microelectronic assembly, comprising:
a substrate having a surface;
a die having a first surface and an opposing second surface, wherein the first surface of the die is coupled to the surface of the substrate by interconnects, and wherein the second surface of the die has a roughness between 100 nanometers and 500 nanometers;
a cooling apparatus thermally coupled to the second surface of the die; and
a material between the second surface of the die and the cooling apparatus.

2. The microelectronic assembly of claim 1, wherein a thickness of the material is between 0.05 millimeters and 2 millimeters, and the thickness is substantially uniform.

3. The microelectronic assembly of claim 1, wherein the material includes a thermal interface material (TIM).

4. The microelectronic assembly of claim 3, wherein the TIM includes a solder-based thermal interface material (STIM) and the STIM is in direct contact with the second surface of the die and with the cooling apparatus.

5. The microelectronic assembly of claim 1, wherein the cooling apparatus includes a heat sink, a heat spreader, an integrated heat spreader, or a cold plate.

6. The microelectronic assembly of claim 1, wherein the interconnects include solder, and the microelectronic assembly further comprising:
an underfill material between the first surface of the die and the surface of the substrate around the interconnects.

7. The microelectronic assembly of claim 1, wherein the die is a first die, and the microelectronic assembly further comprising:
a second die within the substrate and coupled to the first die.

8. The microelectronic assembly of claim 1, wherein the substrate includes a glass core.

9. The microelectronic assembly of claim 1, wherein the surface of the substrate is a second surface and the substrate further having a first surface opposite the second surface, and the microelectronic assembly further comprising:
a circuit board, wherein the circuit board is coupled to the first surface of the substrate.

10. An integrated circuit (IC) package, comprising:
a substrate having a surface and including conductive pathways through a dielectric material;
a die having a first surface and an opposing second surface, wherein the first surface of the die is coupled to the second surface of the substrate by interconnects, and wherein the die has a first thickness that is substantially uniform;
a cooling apparatus thermally coupled to the second surface of the die; and
a solder-based thermal interface material (STIM) between the second surface of the die and the cooling apparatus, wherein the STIM is in direct contact with the second surface of the die and with the cooling apparatus.

11. The IC package of claim 10, wherein the second surface of the die has a roughness between 100 nanometers and 500 nanometers.

12. The IC package of claim 10, wherein the cooling apparatus includes a heat sink, a heat spreader, an integrated heat spreader, or a cold plate.

13. The IC package of claim 10, wherein the interconnects include solder, and the IC package further comprising:
an underfill material between the first surface of the die and the surface of the substrate around the interconnects.

14. The IC package of claim 10, wherein the die is one of a plurality of dies.

15. The IC package of claim 10, wherein a thickness of the STIM between the second surface of the die and the cooling apparatus is between 0.05 millimeters and 1 millimeter.

16. A computing device, comprising:
a substrate having a surface and including conductive pathways through a dielectric material;
a first die having a first surface and an opposing second surface, wherein the first surface of the first die is coupled to the second surface of the substrate by first interconnects, and wherein the second surface of the first die has a roughness between 100 nanometers and 500 nanometers;
a second die having a first surface and an opposing second surface, wherein the first surface of the second die is coupled to the second surface of the substrate by second interconnects, wherein the second surface of the second die has a roughness between 100 nanometers and 500 nanometers;
a cooling apparatus thermally coupled to the second surface of the first die and the second surface of the second die; and
a material between the second surface of the first die and the cooling apparatus and between the second surface of the second die and the cooling apparatus.

17. The computing device of claim 16, wherein the first die has a first thickness that is substantially uniform, wherein the second die has a second thickness that is substantially uniform, and wherein the first thickness is substantially equal to the second thickness.

18. The computing device of claim 16, wherein the material includes a solder-based thermal interface material (STIM).

19. The computing device of claim 18, wherein the STIM is in direct contact with the second surface of the first die, the second surface of the second die, and the cooling apparatus.

20. The computing device of claim 16, wherein a thickness of the material is between 0.05 millimeters and 2 millimeters, and the thickness is substantially uniform.
